(19) United States
(12) Patent Application Publication
(10) Pub. No.: US 2022/0173317 A1
(43) Pub. Date: Jun. 2, 2022

(54) BRIGHT ENTANGLED PHOTON SOURCES

(71) Applicants: Srinivasan Krishnamurthy, Cupertino, CA (US); Paulo Santos, Berlin (DE)

(72) Inventors: Srinivasan Krishnamurthy, Cupertino, CA (US); Paulo Santos, Berlin (DE)

(21) Appl. No.: 17/518,070

(22) Filed: Nov. 3, 2021

Related U.S. Application Data
(60) Provisional application No. 63/109,247, filed on Nov. 3, 2020.

(51) Int. Cl. H01L 49/00

(52) U.S. Cl. CPC H01L 49/006

(57) ABSTRACT

The generation of entangled photons is provided by two-photon emission by an emission center immersed in an optical microcavity (MC). The MC is designed to reduce or to suppress the emission of single photons at the fundamental emission wavelength (λ_{g}) of the emitter and increase the emission for the two-photon emission wavelength (2λ_{g}). A reflector is added only to reflect single photons and will not reflect the biphotons.

This application claims the benefit of U.S. Provisional Application 63/109,247, filed Nov. 3, 2020.

### BACKGROUND

The fast-emerging field of quantum information science promises many orders of magnitude enhancements in imaging, sensing, computing, metrology, and communication, in addition to further understanding of fundamental physics. Although the photon is a quantum phenomenon, the conventional optics is said to use classical photons or non-interacting photons. These photons have multiple states, for example, vertical or horizontal polarization or superposition of photons, thus enabling digital application, but each photon in the beam acts independent of the other photons. In this regime, the signal quality (i.e., intensity, noise rates, etc.) is determined by the number of photons received. However, in the field of quantum optics, the photon states are entangled with that of other photons, because of simultaneous birth or birth from the same origin or both, the nature of the signal depends on the number of states.

Entangled photons are employed for secure (quantum) communication as well as for several other fields, such as high-sensitive interferometry and imaging with high signal-to-noise (SNR) ratios with fewer photons.

Although an entanglement phenomenon leads to higher signal-to-noise (SNR) ratio with fewer photons, the progress and/or system-level deployment is hampered by the lack of efficient and bright entangled photon sources. Consequently, any interrogation with entangled photons is limited to desktop-level measurements, i.e., the distance between the source and the detector being limited to about desk top length.

Currently, entangled photons are generated by spontaneous parametric down conversion (SPDC) in nonlinear crystals or by radiative recombination in semiconductor quantum dots (QDs). The efficiency of SPDC in naturally-occurring crystals such as beta-barium borate (BBO) is extremely low (˜10⁻⁹%), generating only ˜10⁶ biphotons per mW. As a result, very large input powers (˜kW) would be required to generate sufficient biphotons for standoff applications such as Quantum LIDAR (light detection and ranging) and long-distance communications, leading to heat management issues. Secondly, because SPDC is a Poissonian process, at high input intensities, multiple biphotons are generated in a single excitation pulse, which can reduce indistinguishability and lead to errors in quantum algorithm protocols.

The present inventors have recognized that it would be desirable to generate entangled photons “on-demand”, meaning that exactly one pair is generated per excitation pulse. The QDs have been demonstrated to offer such possibility. In QDs, biphotons are generated when two electron-hole pairs, or biexcitons, decay through a two-photon cascade process. If the energy splitting of the intermediate states is sufficiently small, the two decay paths are indistinguishable, and the two photons are entangled. QDs have high efficiency but low throughput because of the Coulomb blockade in three-dimensionally quantized structure. Collecting many QDs together to obtain a high flux is possible, but variations in QD size and shape would reduce the coherence of the generated biphotons. Moreover, QDs require cryogenic cooling for improved quantum confinement.

According to one approach, radiative recombination is used in electrically-pumped quantum wells (QWs) in which the electronic states are from one-dimensional (1D) quantum confinement. In QWs, the biphotons are generated via an intermediate virtual state and thus the biphotons are entangled in energy and polarization. Another advantage of QWs over SPDC is that the biphoton emission is isotropic, rather than directional, which allows multiple biphotons per pulse to be distinguished spatially, so increasing the pump power is less likely to generate double biphoton pairs errors. One drawback of QWs is their low efficiency due to single-photon emission being nearly 10⁵ times more probable than biphoton emission.

The present inventors have recognized that it would be desirable to provide entangled photons for any wavelength between 1 and 12 microns or between short wavelength infrared radiation (SWIR) to long wavelength infrared radiation (LWIR) to achieve beyond background limited sensing and enable target detection at longer ranges with several orders of magnitude lower intensity illumination.

The present inventors have recognized that it would be desirable to provide entangled longwave infrared (LWIR) photons to achieve beyond background limited sensing and enable target detection at longer ranges with several orders of magnitude lower intensity illumination.

The present inventors have recognized that it would be desirable to improve the imaging performance of the existing infrared cameras by employing LIDAR-like operation with entangled photons.

The present inventors have recognized that for longer range applications, a smaller size, brighter, and more efficient source of entangled photons is required. An efficient source of entangled photons will have immediate applications including secure communication, quantum imaging, interferometric positioning, navigation, and timing (PNT) and quantum illumination/LIDAR that employs entanglement amplification of SNR.

### SUMMARY

An exemplary embodiment of the invention enhances the generation of entangled photons by two-photon emission by an emission center immersed in an optical microcavity (MC). According to the exemplary embodiment of the invention, the MC is designed to reduce or to suppress the emission of photons at the fundamental emission wavelength (λ_{g}) of the emitter and increase the emission for the two-photon emission wavelength (2λ_{g}).

A reflector is added to reflect the photons of the fundamental wavelength and not to reflect the biphotons (2λ_{g}). Layers can in principle be designed for reflectivity ratios ideally reaching 100000 to 1. The probability of single photons coming out of the system is reduced to 1:1 with biphotons. That is, if 100,000 single photons are emitted, only 1/100,000 pass through the reflector. One biphoton is emitted and passes through the reflector. This is effectively a 50% efficiency.

However, single photons add up fast and build up an optical field to generate another mechanism (called “stimulated emission”) which increases emission in an uncontrolled fashion. This can be avoided when fewer photons at the fundamental wavelength are emitted in the first place.

An optical cavity can be designed to reduce photon states in the cavity. In such a case, the single photon transition probability is not reduced, but the single photons are starved of any state to which to emit. Physically, the single photon emission rate along the cavity axis is reduced. The single photon emission rate by the luminescence center is strongly reduced due to the lack of photonic decay channels. The structure is designed to reduce the number of single photons emitted from the QW by a factor of ˜1000 and the reflector allowing only 1 in 1000 photons to escape, the one photon emission from the structure is effectively suppressed over biphoton emission from 10⁵ to 1 to 0.1 to 1.

An exemplary embodiment of the invention uses a multiple quantum wells (MQWs)-based device concept to increase the biphoton flux further by removing Coulomb blockade restriction and increase efficiency, and further by suppressing the one-photon emission across the bandgap while simultaneously increasing the biphoton extraction. The exemplary embodiment uses a high Q cavity to engineer the photon density of states to reduce at the one-photon wavelength (λ_{g}) and enhance at biphoton wavelength (2λ_{g}).

The number, called Q, is used to characterize how well an optical cavity stores light: the higher the Q, the longer light stays confined in the cavity. A high Q cavity collects the photon density of states from other wavelengths to enhance considerably at a chosen wavelength. A larger Q means a larger ratio of this density of states in the neighborhood of the chosen wavelength.

The design for the cavity uses a Distributed Bragg Reflector (DBR)—a stack of alternating high and low refractive index dielectrics design—for high reflection around the one-photon emission wavelength λ_{g} and high transmission around the biphoton emission wavelength 2λ_{g}.

The approach uses a quantum structure for photon emitter inserted in an MC to increase the biphoton (i) flux by removing the Coulomb blockade restriction, (ii) efficiency by suppressing the emission and transmission of one-photons across the bandgap with the natural emitter wavelength (λ_{g}) while simultaneously allowing the biphotons of wavelength 2λ_{g} emission without any restriction. By choosing QW instead of QD, Coulomb blockade is naturally removed.

The efficiency increase is achieved by the design which is engineered specifically to include (a) distributed Bragg reflectors (DBRs) for all-angle high reflection at the emitter wavelength (λg) and (b) a MC to optimize the photon density of states at the photon emitter position to reduce the emission of one-photons at wavelength (λg) and enhance at biphoton emission at wavelength (2λg).

The use of entangled photons promises many orders of magnitude enhancements in imaging, sensing, computing, metrology, and communication. For example, the coincidence measurements—between returned signal photons and idler photons—would enable one to clearly distinguish a signal photon from a noise photon, leading to a large increase in the SNR. The increased SNR can be exploited to detect far away objects with increased image quality and/or observe objects with very low intensity illumination—in stealth mode—at lower power consumption. All these applications also benefit substantially from architecture simplification and improved performance.

The entangled photons can be provided for any wavelength between 1 and 12 microns or between short wavelength infrared radiation (SWIR) to long wavelength infrared radiation (LWIR). This can achieve beyond background limited sensing and enable target detection at longer ranges with several orders of magnitude lower intensity illumination.

The method and article of the invention can work for many quantum emitters (QEs) including: quantum dots, quantum wire, quantum well, or multiple quantum wells.

Numerous other advantages and features of the present invention will be become readily apparent from the following detailed description of the invention and the embodiments thereof, and from the accompanying drawings.

### BRIEF DESCRIPTION OF THE DRAWINGS

FIG. 1(a) is a schematic sectional view of an exemplary embodiment of the invention;

FIG. 1(b) is a schematic energy level diagram of the embodiment of FIG. 1(a); and

FIG. 2 is a schematic sectional view of an alternate embodiment of the invention.

### DETAILED DESCRIPTION

While this invention is susceptible of embodiment in many different forms, there are shown in the drawings, and will be described herein in detail, specific embodiments thereof with the understanding that the present disclosure is to be considered as an exemplification of the principles of the invention and is not intended to limit the invention to the specific embodiments illustrated.

An exemplary embodiment of the invention uses a QE in the form of quantum well (QW) in a device concept to increase the biphoton flux further by removing Coulomb blockade restriction and increase efficiency further by suppressing the one-photon emission across the bandgap while simultaneously increasing the biphoton extraction. The exemplary embodiment uses a special high Q cavity engineered to reduce the photon density of states at the one-photon wavelength (λ_{g}) and to enhance the photon density of states at biphoton wavelength (2λ_{g}). The design for the cavity uses a Distributed Bragg Reflector (DBR)—a stack of alternating high and low refractive index dielectrics design for high reflection around λ_{g} and high transmission around 2λ_{g}

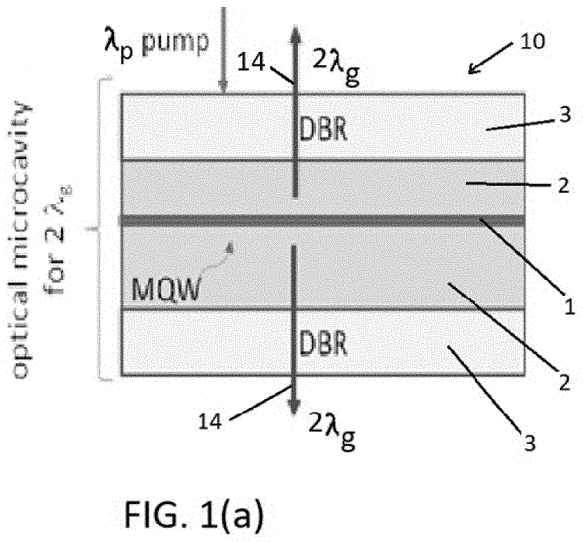

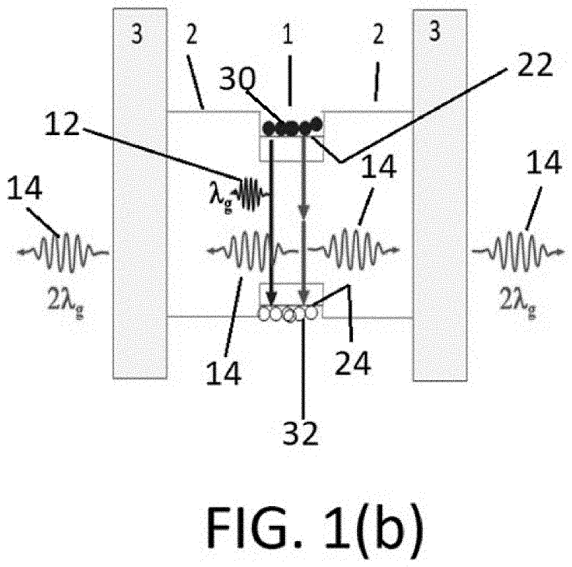

FIGS. 1(a)-1(b) illustrate a schematic design of an optically injected device 10. FIG. 1(a) illustrates the schematic sectional view of the device 10. Bars denote a series of QW 1, barrier 2 and DBRs 3. Pump photons propagate through the DBR and are absorbed in the barrier located beneath the DBR.

FIG. 1(b) illustrates an energy level line up of this device. The QW 1 is embedded in between the barriers 2 which is a wider band gap dielectric and sandwiched between the two DBRs 3 to form a microcavity resonant at 2λ_{g}. In both figures, any emitted photon 12 of wavelength λ_{g} is reflected by the DBR. The emission of biphotons 14 of wavelength 2λ_{g} is enhanced via the Purcell effect induced by the microcavity. These biphotons are transmitted through the DBRs.

The QW is designed to have a band gap energy smaller than that of the barrier 2.

Because the carriers in the QW structure are constrained, the states are quantized in conduction and valence bands to yield states to be larger than the bulk band gap of the QW material, as shown by lines 22, 24. The QW is designed to have fundamental emission at the wavelength of λ_{g}. The pump photons of wavelength λ_{P}, are launched into the device normal to the barrier and normal to the DBR, and into the cavity, the region between two DBRs. The pump photons are absorbed in the barrier 2 creating electron-hole (e-h) pairs (filled and unfilled circles in FIG. 1b) which are transferred to the QW.

The pump photons are absorbed in the barriers and are transferred to the QW, creating electrons 30 (filled circles in FIG. 1b) and holes 32 (hollow circles in FIG. 1b). In the QW, those carriers, electrons and holes, will recombine by process: (a) emitting one-photons 12 with wavelength λ_{g}, (b) non-radiatively (not shown), and (c) emitting biphotons 14 with wavelength 2λ_{g}. The nonradiative recombination rates mediated by the Shockley-Read-Hall process can be minimized by defect-free growth with a low impurity concentration. Non-radiative Auger processes can be kept to a minimum by keeping the carrier density <10¹⁷ cm³.

The direct competition determining the emission efficiency for 2λ_{g} biphotons is between processes (a) and (c). If left to themselves, process (a) would dominate as the one-photon emission rate is about 10⁵ times larger than the two-photon emission rate. However, two features are added to overcome this disadvantage. First, the QWs are placed at the location where the one-photon density of states is near zero, thus reducing the number of emitted photons to be very little. Then, all-angle reflecting DBRs (Region 3) are added to reflect all emitted one-photons back to QW, thus maintaining a near-constant electron-hole (e-h) density in the QW (Region 1). These two features force e-h pairs to decay through two-photon emission at wavelength 2λ_{g}. The micro cavity (MC) anti-resonates at λ_{g} and it doesn't affect the emission at 2λ_{g}. In addition, the DBRs are carefully designed to have over 90% transmission of 2λ_{g} photons.

For example, the design and materials can be chosen to produce entangled photons of wavelength 10.6 μm. The DBR materials can be CdTe (low index) and Hg_{0.28}Cd_{0.72}Te (high index). The spacers 2 can each be 1200 nm thickness of Hg_{0.60}Cd_{0.40}Te and the well region 1 can be 1.5 nm thickness of HgTe for an LWIR design. The calculated optical property of the cavity with the MQWs indicate near zero emission of 5.3 μm photons and over 90% transmission of 10.6 μm photons, leading to an efficiency of about 1.2%, which is 5 orders of magnitude larger the current state of art.

As another example for generation of biphotons of wavelength 1550 nm, the device can alternately be comprised of Ga₁₋ₓAlₓAs (x=0.3) for the barrier and Ga₁₋ₓAlₓAs (x=0.10) for the QWs, and AlAs/Ga₁₋ₓAlₓAs (x=0.5) for the DBR. The calculated optical property of the cavity with the MQWs indicate near zero emission of 0.775 μm photons and over 90% transmission of 1.55 μm photons, leading to an efficiency of about 66%, which is 6 orders of magnitude larger the current state of art.

In addition, a higher density of biphoton emission is possible in the device because the carrier density in QW is not limited by Coulomb blockade as in the case of QDs. The electron-hole recombination takes place at the center r of the Brillouin Zone and thus biphotons are emitted at random direction with their momentum adding to zero. In other words, the biphotons are emitted 4π steradian within the cavity, instead of a narrow cone in the SPDC approach. As the biphotons exit the DBRs, the angular distribution will be narrow and determined by cavity design. The larger angular distribution enables the increase in the emitted photon density without adding time-bin errors. Even more importantly, the photons will be entangled in energy, polarization, and space. The hyper entanglement improves the SNR even more. By recycling the single photons, this device is expected to provide orders of magnitude improvement in the efficiency of biphoton generation compared to natural χ(2) crystals. The designs can be grown with molecular-beam epitaxy (MBE) or Metal Organic Chemical Vapor Deposition (MOCVD) and fabricated with standard processing methods and are amenable for monolithic integration thus improving in size, weight, and power (SWaP) performance.

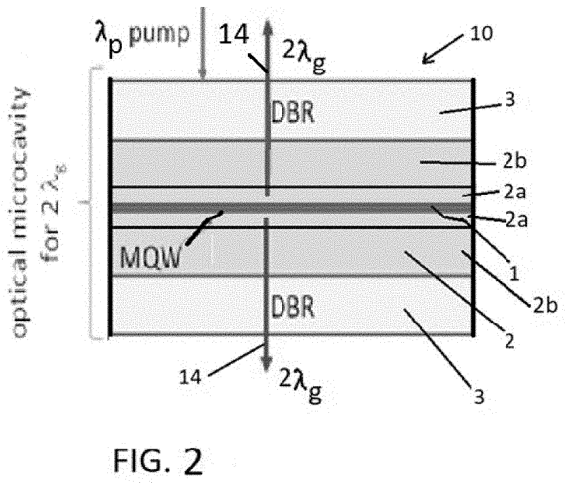

FIG. 2 illustrates an alternate embodiment wherein each barrier 2 of FIG. 1(a) is replaced by a barrier layer 2a and a separate spacer layer 2b. The barrier layer is chosen appropriately for the chosen pump wavelength and thickness is chosen to stay within diffusion length of photocarrier in that material. The spacer layer does not have this limitation, except it has to be transparent to pump. The spacer layer can be added without affecting any quantum property, only to make sure that the fundamental emission suppressed by designing low density of states for photons. In cases like HgCdTe for LWIR, the diffusion length is in microns and so the barrier thickness can be varied to optimize the field for suppression. Wherein in cases like GaAlAs for SWIR, the diffusion length is 100 nm and additional space is needed to optimize the field.

From the foregoing, it will be observed that numerous variations and modifications may be incorporated without departing from the spirit and scope of the invention. It is to be understood that no limitation with respect to the specific apparatus illustrated herein is intended or should be inferred.

The invention claimed is:

1. A device for increasing biphoton emission from a photon source, comprising:
one or more quantum emitters cladded by a wider band gap quantum barrier;
and a Distributed Bragg Reflector, configured for high reflection and high suppression of emission at λ_{g} while maintaining high transmission at 2λ_{g}.

2. The device according to claim 1, wherein the Distributed Bragg Reflector is composed of alternating layers of low index material and a high index material.

3. The device according to claim 1, wherein the quantum emitters comprise quantum wells, and quantum barrier and the wells are made of Hg_{0.6}Cd_{0.4}Te and HgTe respectively.

4. The device according to claim 1, wherein the quantum emitters comprise quantum wells, wherein the barrier can be 1200 nm-thick Hg_{0.6}Cd_{0.4}Te and the quantum wells can be 1.5 nm thick of HgTe.

5. The device according to claim 1, wherein the quantum emitters comprise quantum wells, wherein the quantum wells are composed of Ga₁₋ₓAlₓAs (x=0.10), the quantum barrier is composed of Ga₁₋ₓAlₓAs (x=0.30), and Distributed Bragg Reflector are composed of AlAs/Ga₁₋ₓAlₓAs(x=0.5) alloys.
